(19) United States
(12) Patent Application Publication
(10) Pub. No.: US 2023/0081969 A1
(43) Pub. Date: Mar. 16, 2023

(54) PREPARATION METHOD FOR SPHERICAL SILICA POWDER FILLER, POWDER FILLER OBTAINED THEREBY AND USE THEREOF

(71) Applicant: ZHEJIANG THIRD AGE MATERIAL TECHNOLOGY CO., LTD, Huzhou (CN)

(72) Inventors: Shuzhen CHEN, Huzhou (CN); Rui LI, Huzhou (CN); Ke WANG, Huzhou (CN); Lieping DING, Huzhou (CN); Chen CHEN, Huzhou (CN)

(21) Appl. No.: 17/799,763

(22) PCT Filed: Feb. 17, 2020
(86) PCT No.: PCT/CN2020/075559

§ 371 Date: Aug. 15, 2022

(51) Int. Cl. C09C 1/30; C08G 77/12; C01B 33/18; C08K 9/06

(52) U.S. Cl. CPC C09C 1/3081; C08G 77/12; C01B 33/181; C08K 9/06; C01P 2004/32; C01P 2004/62; C01P 2004/61; C08K 2201/005; C08G 77/70

(57) ABSTRACT

A preparation method for a spherical silica powder filler comprises the following steps: S1, providing spherical polysiloxane comprising a T unit by means of a hydrolysis condensation reaction of R₁SiX₃, wherein R₁ is hydrogen atom or an organic group having independently selectable 1 to 18 carbon atoms, X is a hydrolyzable group, and T unit is R₁SiO₃—; and S2, calcining the spherical polysiloxane under the condition of a dry oxidizing gas atmosphere, the calcining temperature being between 850° C. and 1200° C., so as to obtain the spherical silica powder filler which does not contain silica particles of which the diameter is less than 50 nanometers. The spherical silica powder filler does not contain silica particles of which the diameter is less than 50 nanometers, has a low dielectric loss and a low thermal expansion coefficient, and is suitable for high-frequency high-speed circuit boards, prepregs or copper clad laminates, etc.

### BACKGROUND OF THE INVENTION

### 1. Field of the Invention

The present invention relates to circuit boards, and more particularly to a preparation method for a spherical silica powder filler, powder filler obtained thereby and use.

### 2. Related Art

In the field of 5G communication, equipments assembled by the radio frequency devices and circuit boards such as high-density interconnect boards (HDI), high-frequency high-speed boards and motherboards, etc. are required. These circuit boards are generally composed of fillers and organic polymers such as epoxy resin, aromatic polyether and fluororesin, etc. The fillers are mainly angular or spherical silica whose main function is to reduce the thermal expansion coefficient of organic polymers. The spherical or angular silica is tightly packed and graded in the existing fillers.

On the one hand, with the advancement of technology, the signal frequency used by semiconductors is getting higher and higher, and the high-speed and low-loss signal transmission speed requires fillers with low dielectric loss and low dielectric constant. The dielectric constant of material basically depends on its chemical composition and structure, and silica has its inherent dielectric constant. On the other hand, the dielectric loss is related to the adsorbed moisture content of the filler, the more the moisture content, the greater the dielectric loss. The high-temperature flame heating method is commonly used for the traditional spherical silica, wherein the physical melting or chemical oxidation is used to prepare the spherical silica. The flame temperature is generally higher than the boiling point of silica at 2230 degrees, causing the generation of silica below tens of nanometers (such as below 50 nm) by condensed after gasification. The specific surface area and diameter of spherical silica have a reciprocal function relationship: specific surface area=constant/particle diameter. That is, a decrease in diameter leads to a sharp increase in specific surface area. For example, the calculated specific surface area of spherical silica with a diameter of 0.5 μm is 5.6 m²/g, and the calculated specific surface area of spherical silica with a diameter of 50 nm is 54.5 m²/g. In addition, water molecules are adsorbed on the surface of silica, thus spherical silica powder filler containing silica particles of which the diameter is less than 50 nanometers has a high water content, resulting in an increased dielectric loss, which cannot meet the requirement for the dielectric properties of high-frequency and high-speed circuit boards in the 5G communication era.

### SUMMARY OF THE INVENTION

In order to solve the problem that the silica powder filler contains silica particles of which the diameter is less than 50 nanometers in the prior art, the present invention provides a preparation method for a spherical silica powder filler, powder filler obtained thereby and use.

The present invention provides a preparation method for a spherical silica powder filler, comprising the following steps: S1, providing spherical polysiloxane comprising a T unit by means of a hydrolysis condensation reaction of R₁SiX₃, wherein R₁ is hydrogen atom or an organic group having independently selectable 1 to 18 carbon atoms, X is a hydrolyzable group, and T unit is R₁SiO₃—; S2, calcining the spherical polysiloxane under the condition of a dry oxidizing gas atmosphere, the calcining temperature being between 850 degrees and 1200 degrees, so as to obtain the spherical silica powder filler which does not contain silica particles of which the diameter is less than 50 nanometers.

Preferably, the hydrolyzable group X is an alkoxy group such as a methoxy group, an ethoxy group, and a propoxy group, etc, or a halogen atom such as a chlorine atom, etc. The catalyst for the hydrolysis condensation reaction may be a base and/or an acid.

Preferably, a speed of the hydrolysis condensation reaction is controlled to prevent from generating the polysiloxane particles of which the diameter is less than 50 nanometers. As long as it does not substantially contain polysiloxane particles of which the diameter is less than 50 nanometers, the present invention has no particular limitation on the synthesis method of polysiloxane.

In a preferred embodiment, methyltrimethoxysilane or propyltrimethoxysilane is hydrolyzed and dissolved in deionized water under acidic conditions (for example, the pH is adjusted to about 5 with acetic acid), and then ammonia water (for example, the ammonia water with a mass fraction of 5%) is added, thus the condensation is performed under alkaline conditions to obtain spherical polysiloxane. In particular, the temperature of the hydrolysis reaction is between room temperature and 70 degrees. At this time, the concentration of the hydrolyzed product of methyltrimethoxysilane or propyltrimethoxysilane in water should not be too low, in order to avoid the generation of polysiloxane particles of which the diameter is less than 50 nanometers. In particular, the mass ratio of water to methyltrimethoxysilane or propyltrimethoxysilane is between 600-2500:80. For example, deionized water at room temperature is added into a reactor with a stirrer, methyltrimethoxysilane or propyltrimethoxysilane and acetic acid are added while stirring, then the stirring is stopped, after standing still, it was filtered and dried to obtain spherical polysiloxane.

In another preferred embodiment, methyltrimethoxysilane or propyltrimethoxysilane is added to the top of dilute ammonia water to keep the separated state of the oil phase and water phase, and methyltrimethoxysilane or propyltrimethoxysilane is hydrolyzed and migrated to the water phase at the oil-water interface by the slow stirring, and the migrated hydrolyzed product is condensed in the water phase to form spherical polysiloxane particles. At this time, the ratio of methyltrimethoxysilane or propyltrimethoxysilane to dilute ammonia water should not be too low, in order to avoid the generation of polysiloxane particles of which the diameter is less than 50 nanometers.

Preferably, the oxidizing gas contains oxygen to oxidize all the organics in the polysiloxane. For saving cost, the oxidizing gas is the air. In order to reduce the hydroxyl content of the calcined silica, the less moisture content in the air, the better. For saving cost, the compressed air after removing water by a freeze dryer is suitable for the calcination atmosphere of the present invention. The present invention has no particular limitation on the heating method. However, since the gas burner contains moisture, the direct heating by the gas flame should be avoided in the present invention. Electric heating or gas indirect heating is more suitable for the present invention. The temperature can be gradually increased during calcination. Slow heating at temperature lower than 850 degrees and room temperature is beneficial to the slow decomposition of organic groups, in order to reduce the residual carbon in the final silica after the calcination. When the amount of residual carbon is high, the whiteness of silica decreases. Specifically, the step S2 comprises that the spherical polysiloxane powder is put into a muffle furnace and dry air is introduced for calcination.

Preferably, the calcining temperature is between 850 degrees and 1100 degrees, and the calcining time is between 6 hours and 12 hours.

Preferably, the spherical polysiloxane further comprises a Q unit, a D unit, and/or a M unit, wherein Q unit is SiO₄—, D unit is R₂R₃SiO₂—, M unit is R₄R₅R₆SiO—, wherein each of R₂, R₃, R₄, R₅, R₆ is a hydrogen atom or an hydrocarbon group having independently selectable 1 to 18 carbon atoms. For example, in a preferred embodiment, Si(OC₂C₃)₄, CH₃CH₃Si(OCH₃)₂ can be combined with CH₃Si(OCH₃)₃.

Preferably, the preparation method further comprises adding a treatment agent to perform surface treatment on the spherical silica powder filler, and the treatment agent comprises a silane coupling agent and/or disilazane; the silane coupling agent is (R₇)ₐ(R₈)_{b}Si(M)_{4-a-b}, wherein each of R₇, R₈ is a hydrogen atom, an hydrocarbon group having independently selectable 1 to 18 carbon atoms, or an hydrocarbon group having independently selectable 1 to 18 carbon atoms replaced by a functional group, wherein the functional group is selected from at least one of the following organic functional groups: vinyl, allyl, styryl, epoxy group, aliphatic amino, aromatic amino, methacryloxypropyl, acryloyloxypropyl, ureidopropyl, chloropropyl, mercaptopropyl, polysulfide group, isocyanate propyl; M is an alkoxy group with 1 to 18 carbon atoms or a halogen atom, a is 0, 1, 2 or 3, b is 0, 1, 2 or 3, a+b is 1, 2 or 3; the disilazane is (R₉R₁₀R₁₁)SiNHSi(R₁₂R₁₃R₁₄), wherein each of R₉, R₁₀, R₁₁, R₁₂, R₁₃, R₁₄ is a hydrogen atom or an hydrocarbon group having independently selectable 1 to 18 carbon atoms.

The present invention also provides a spherical silica powder filler obtained according to the above-mentioned preparation method, wherein the spherical silica powder filler does not contain silica particles of which the diameter is less than 50 nanometers, and an average particle size of the spherical silica powder filler is between 0.1 μm and 5 μm. More preferably, the average particle size of the spherical silica powder filler is between 0.15 μm and 4.5 μm.

The present invention also provides a use of the spherical silica powder filler, wherein the spherical silica powder filler of different particle sizes is tightly packed and graded in resin to form a composite material, which is suitable for circuit board material and semiconductor packaging material. Preferably, the spherical silica powder filler is suitable for high-frequency high-speed circuit boards, prepregs, copper clad laminates and other semiconductor packaging materials that require low dielectric loss.

Preferably, coarse particles above 1 μm, 3 μm, 5 μm, 10 μm, or 20 μm in the spherical silica powder filler are removed by a dry or wet sieving or inertial classification.

The spherical silica powder filler according to the present invention does not contain silica particles of which the diameter is less than 50 nanometers, has a low dielectric loss and a low thermal expansion coefficient, and is suitable for high-frequency high-speed circuit boards, prepregs or copper clad laminates, etc.

### DESCRIPTION OF THE ENABLING EMBODIMENT

The preferred embodiments of the present invention are given below and described in detail.

The detection methods involved in the following embodiments are listed as follows.

The average particle size is measured with HORIBA's laser particle size distribution analyzer LA-700.

The presence or absence of silica particles of which the diameter is less than 50 nanometers is directly observed with a field emission scanning electron microscope (FE-SEM). When no spherical silica particle of which the diameter is less than 50 nanometers is substantially observed in random ten photos of 20,000 magnifications, the spherical silica powder filler does not contain silica particles of which the diameter is less than 50 nanometers.

The dielectric loss test method comprises: mixing different volume fractions of sample powders and paraffin to make test samples, and using a commercially available high-frequency dielectric loss meter to measure the dielectric loss under the condition of 10 GHz. Then the dielectric loss of the sample is obtained from the slope in the coordinate, wherein the ordinate represents the dielectric loss, and the abscissa represents the volume fraction. The dielectric losses of the Examples and Comparative Examples of the present invention at least can be relatively compared although it is generally difficult to obtain the absolute value of the dielectric loss.

In this text, “degrees” refers to Celsius degrees, i.e., ° C.

In this text, the average particle size refers to the volume average diameter of the particles.

### Embodiment 1

Deionized water of a certain weight at room temperature was added into a reactor with a stirrer. While stirring, methyltrimethoxysilane of 80 by weight was added and a small amount of acetic acid was added to adjust the pH to about 5. After the methyltrimethoxysilane was dissolved, 5% ammonia water of 25 by weight was added and stirred for 10 seconds, and then the stirring was stopped. After standing for 1 hour, it was filtered and dried to obtain spherical polysiloxane. The polysiloxane powder was put into a muffle furnace and dry air was introduced for calcination. The final calcining temperature was 850 degrees, 1000 degrees or 1100 degrees, and the calcining time was 12 hours. The analysis results of the samples were listed in following Table 1.

TABLE 1

| | | | | Silica | |
|---|---|---|---|---|---|
| | | Average | Final | Particle of | |
| | Deionized | Particle | Calcining | Diameter | Dielectric |
| | Water by | Size | Temperature | less than | Loss |
| | Weight | (μm) | (° C.) | 50 nm | (10 GHz) |
| Example 1 | 1500 | 0.8 | 1000 | None | 0.00005 |
| Example 2 | 1100 | 1.2 | 1100 | None | 0.00003 |
| Example 3 | 800 | 3.0 | 850 | None | 0.00008 |
| Example 4 | 600 | 4.5 | 1100 | None | 0.00002 |

### Embodiment 2

Deionized water of 1100 by weight at room temperature was added into a reactor with a stirrer. While stirring, propyltrimethoxysilane of 80 by weight was added and a small amount of acetic acid was added to adjust the pH to about 5. After the propyltrimethoxysilane was dissolved, 5% ammonia water of 25 by weight was added and stirred for 10 seconds, and then the stirring was stopped. After standing for 1 hour, it was filtered and dried to obtain spherical polysiloxane. The polysiloxane powder was put into a muffle furnace and dry air was introduced for calcination. The final calcining temperature was 950 degrees, and the calcining time was 6 hours. The analysis result of the sample was listed in following Table 2.

TABLE 2

| | Average | Final Calcining | Silica Particle | Dielectric |
|---|---|---|---|---|
| | Particle | Temperature | of Diameter less | Loss |
| | Size (μm) | (° C.) | than 50 nm | (10 GHz) |
| Example 5 | 0.6 | 950 | None | 0.00006 |

### Embodiment 3

Deionized water of 2500 by weight at 40° C. was added into a reactor with a stirrer. While stirring, methyltrimethoxysilane of 80 by weight was added and a small amount of acetic acid was added to adjust the pH to about 5. After the methyltrimethoxysilane was dissolved, 5% ammonia water of 60 by weight was added and stirred for 10 seconds, and then the stirring was stopped. After standing for 1 hour, it was filtered and dried to obtain spherical polysiloxane. The polysiloxane powder was put into a muffle furnace and dry air was introduced for calcination. The final calcining temperature was 1000 degrees, and the calcining time was 12 hours. The analysis result of the sample was listed in following Table 3.

TABLE 3

| | Average | Final Calcining | Silica Particle | Dielectric |
|---|---|---|---|---|
| | Particle | Temperature | of Diameter less | Loss |
| | Size (μm) | (° C.) | than 50 nm | (10 GHz) |
| Example 6 | 0.15 | 1000 | None | 0.00009 |

### Embodiment 4

Deionized water of 5000 by weight at 70° C. was added into a reactor with a stirrer. While stirring, methyltrimethoxysilane of 80 by weight was added and a small amount of acetic acid was added to adjust the pH to about 5. After the methyltrimethoxysilane was dissolved, 5% ammonia water of 200 by weight was added and stirred for 1 hour. It was filtered and dried to obtain spherical polysiloxane. The polysiloxane powder was put into a muffle furnace and dry air was introduced for calcination. The final calcining temperature was 1000 degrees, and the calcining time was 12 hours. The analysis result of the sample was listed in following Table 4.

TABLE 4

| | Average | Final Calcining | Silica Particle | Dielectric |
|---|---|---|---|---|
| | Particle | Temperature | of Diameter less | Loss |
| | Size (μm) | (° C.) | than 50 nm | (10 GHz) |
| Comparative | 0.30 | 1000 | Exist | 0.00025 |
| Example 1 | | | | |

### Embodiment 5

The crushed silica with an average particle size of 2 μm was sent to a spheroidizing furnace with a flame temperature of 2500 degrees for melting and spheroidizing. All the spheroidized powders were collected as sample of Comparative Example 2. The analysis result of the sample was listed in following Table 5.

TABLE 5

| | Average | Silica Particle | Dielectric |
|---|---|---|---|
| | Particle | of Diameter less | Loss |
| | Size (μm) | than 50 nm | (10 GHz) |
| Comparative | 3.0 | Exist | 0.001 |
| Example 2 | | | |

It should be understood that the samples obtained in the Examples 1-6 may be surface-treated. Specifically, vinyl silane coupling agent, epoxy silane coupling, disilazane, etc. can be used to treat the samples as required. Also, at least two treatment agents can be used to treat the samples as required.

It should be understood that coarse particles above 1 μm, 3 μm, 5 μm, 10 μm, or 20 μm in the spherical silica powder filler are removed by a dry or wet sieving or inertial classification.

It should be understood that the spherical silica powder filler of different particle sizes is tightly packed and graded in resin to form a composite material.

The foregoing description refers to preferred embodiments of the present invention and is not intended to limit the scope of the present invention. Various changes can be made to the foregoing embodiments of the present invention. That is to say, all simple and equivalent changes and modifications made in accordance with the claims of the present invention and the content of the description fall into the protection scope of the patent of the present invention. What is not described in detail in the present invention is conventional technical content.

1. A preparation method for a spherical silica powder filler, comprising the following steps:
S1, providing spherical polysiloxane comprising a T unit by means of a hydrolysis condensation reaction of R₁SiX₃, wherein R₁ is hydrogen atom or an organic group having independently selectable 1 to 18 carbon atoms, X is a hydrolyzable group, and T unit is R₁SiO₃—; and
S2, calcining the spherical polysiloxane under a condition of a dry oxidizing gas atmosphere, the calcining temperature being between 850° C. and 1200° C., so as to obtain the spherical silica powder filler which does not contain silica particles of which the diameter is less than 50 nanometers.

2. The preparation method according to claim 1, wherein the hydrolyzable group is an alkoxy group or a halogen atom.

3. The preparation method according to claim 1, wherein a speed of the hydrolysis condensation reaction is controlled to prevent from generating the polysiloxane particles of which the diameter is less than 50 nanometers.

4. The preparation method according to claim 1, wherein the oxidizing gas contains oxygen to oxidize all the organics in the polysiloxane.

5. The preparation method according to claim 1, wherein the calcining temperature is between 850° C. and 1100° C., and the calcining time is between 6 hours and 12 hours.

6. The preparation method according to claim 1, wherein the spherical polysiloxane further comprises a Q unit, a D unit, and/or a M unit, wherein Q unit is SiO₄—, D unit is R₂R₃SiO₂—, M unit is R₄R₅R₆SiO—, wherein each of R₂, R₃, R₄, R₅, R₆ is a hydrogen atom or an hydrocarbon group having independently selectable 1 to 18 carbon atoms.

7. The preparation method according to claim 1, wherein the preparation method further comprises adding a treatment agent to perform surface treatment on the spherical silica powder filler, and the treatment agent comprises a silane coupling agent and/or disilazane;
the silane coupling agent is (R₇)ₐ(R₈)_{b}Si(M)_{4-a-b}, wherein each of R₇, R₈ is a hydrogen atom, an hydrocarbon group having independently selectable 1 to 18 carbon atoms, or an hydrocarbon group having independently selectable 1 to 18 carbon atoms replaced by a functional group, wherein the functional group is selected from at least one of the following organic functional groups: vinyl, allyl, styryl, epoxy group, aliphatic amino, aromatic amino, methacryloxypropyl, acryloyloxypropyl, ureidopropyl, chloropropyl, mercaptopropyl, polysulfide group, isocyanate propyl;
M is an alkoxy group with 1 to 18 carbon atoms or a halogen atom, a is 0, 1, 2 or 3, b is 0, 1, 2 or 3, a+b is 1, 2 or 3; and
the disilazane is (R₉R₁₀R₁₁)SiNHSi(R₁₂R₁₃R₁₄), wherein each of R₉, R₁₀, R₁₁, R₁₂, R₁₃, R₁₄ is a hydrogen atom or an hydrocarbon group having independently selectable 1 to 18 carbon atoms.

8. A spherical silica powder filler obtained according to the preparation method of claim 1, wherein the spherical silica powder filler does not contain silica particles of which the diameter is less than 50 nanometers, and an average particle size of the spherical silica powder filler is between 0.1 μm and 5 μm.

9. A use of the spherical silica powder filler according to claim 8, wherein the spherical silica powder filler of different particle sizes is tightly packed and graded in resin to form a composite material, which is suitable for circuit board material and semiconductor packaging material.

10. The use according to claim 9, wherein coarse particles above 1 μm, 3 μm, 5 μm, 10 μm, or 20 μm in the spherical silica powder filler are removed by a dry or wet sieving or inertial classification.

11. A spherical silica powder filler obtained according to the preparation method of claim 2, wherein the spherical silica powder filler does not contain silica particles of which the diameter is less than 50 nanometers, and an average particle size of the spherical silica powder filler is between 0.1 μm and 5 μm.

12. A spherical silica powder filler obtained according to the preparation method of claim 3, wherein the spherical silica powder filler does not contain silica particles of which the diameter is less than 50 nanometers, and an average particle size of the spherical silica powder filler is between 0.1 μm and 5 μm.

13. A spherical silica powder filler obtained according to the preparation method of claim 4, wherein the spherical silica powder filler does not contain silica particles of which the diameter is less than 50 nanometers, and an average particle size of the spherical silica powder filler is between 0.1 μm and 5 μm.

14. A spherical silica powder filler obtained according to the preparation method of claim 5, wherein the spherical silica powder filler does not contain silica particles of which the diameter is less than 50 nanometers, and an average particle size of the spherical silica powder filler is between 0.1 μm and 5 μm.

15. A spherical silica powder filler obtained according to the preparation method of claim 6, wherein the spherical silica powder filler does not contain silica particles of which the diameter is less than 50 nanometers, and an average particle size of the spherical silica powder filler is between 0.1 μm and 5 μm.

16. A spherical silica powder filler obtained according to the preparation method of claim 7, wherein the spherical silica powder filler does not contain silica particles of which the diameter is less than 50 nanometers, and an average particle size of the spherical silica powder filler is between 0.1 μm and 5 μm.
